(19) United States
(12) Patent Application Publication
(10) Pub. No.: US 2025/0125256 A1
(43) Pub. Date: Apr. 17, 2025

(54) SEMICONDUCTOR PACKAGE

(71) Applicant: SAMSUNG ELECTRONICS CO., LTD., Suwon-si (KR)

(72) Inventors: Jae Sup Lee, Suwon-si (KR); Sol Hee In, Suwon-si (KR); Do Hyung Kim, Suwon-si (KR); Byung Wook Jung, Suwon-si (KR)

(21) Appl. No.: 18/885,973

(22) Filed: Sep. 16, 2024

(30) Foreign Application Priority Data
Oct. 12, 2023 (KR) 10-2023-0135821

(51) Int. Cl. H01L 23/522; H01L 23/00; H01L 23/498; H01L 23/64; H01L 25/16

(52) U.S. Cl. CPC H01L 23/5227; H01L 23/645; H01L 23/49833; H01L 23/49838; H01L 24/16; H01L 25/16; H01L 2224/16225; H01L 2924/19042

(57) ABSTRACT

A semiconductor package includes a first substrate that includes a first side and a second side opposite to each other; a semiconductor chip on the second side of the first substrate, and includes a third side and a fourth side opposite to each other; a second substrate between the second side of the first substrate and the third side of the semiconductor chip, and includes a fifth side and a sixth side opposite to each other; a first connecting structure electrically connecting the first substrate and the second substrate, between the first substrate and the second substrate; a second connecting structure electrically connecting the second substrate and the semiconductor chip, between the second substrate and the semiconductor chip; and a coil structure that includes a plurality of conductive layers, and is placed in at least one of the first substrate, the second substrate, and the semiconductor chip.

### CROSS-REFERENCE TO RELATED APPLICATION

This application claims priority to Korean Patent Application No. 10-2023-0135821, filed in the Korean Intellectual Property Office on Oct. 12, 2023, the disclosure of which is incorporated by reference herein in its entirety.

### BACKGROUND

Typically, a semiconductor package may have a structure in which semiconductor chips are mounted on a printed circuit board (PCB) and they are electrically connected using bonding wires or bumps. With the development of the electronics industry, there are increasing demands for a high functionality, a high speed, and a small size of the semiconductor package. In the trend in which the use of electronic products increases to higher frequency bands and the power consumption rises, inductors are being treated as very important components. For example, in order to configure communicating circuits, inductors that may exhibit high characteristics are required.

### SUMMARY

In general, in some aspects, the present disclosure is directed toward a semiconductor package including a coil structure having high performance characteristics.

According to some aspects of the present disclosure, a semiconductor package includes a first substrate which includes a first side and a second side opposite to each other; a semiconductor chip which is placed on the second side of the first substrate, and includes a third side and a fourth side opposite to each other; a second substrate which is placed between the second side of the first substrate and the third side of the semiconductor chip, and includes a fifth side and a sixth side opposite to each other; a first connecting structure which electrically connects the first substrate and the second substrate, between the first substrate and the second substrate; a second connecting structure which electrically connects the second substrate and the semiconductor chip, between the second substrate and the semiconductor chip; and a coil structure which includes a plurality of conductive layers, and is placed in at least one of the first substrate, the second substrate, and the semiconductor chip.

According to some aspects of the present disclosure, a semiconductor package includes a first substrate which includes a first side and a second side opposite to each other; a semiconductor chip which is placed on the second side of the first substrate, and includes a third side and a fourth side opposite to each other; a second substrate which is placed between the second side of the first substrate and the third side of the semiconductor chip, and includes a fifth side and a sixth side opposite to each other; a first connecting structure which electrically connects the first substrate and the second substrate, between the first substrate and the second substrate; a second connecting structure which electrically connects the second substrate and the semiconductor chip, between the second substrate and the semiconductor chip; a coil structure which includes a plurality of conductive layers, and is placed in at least one of the first substrate and the semiconductor chip; and a through via structure which is placed between the first connecting structure and the second connecting structure in the second substrate, and electrically connected to the coil structure.

In some aspects of the present disclosure, a semiconductor package includes a first substrate which includes a first side and a second side opposite to each other; a semiconductor chip which is placed on the second side of the first substrate, and includes a third side and a fourth side opposite to each other; a second substrate which is placed between the second side of the first substrate and the third side of the semiconductor chip, and includes a fifth side and a sixth side opposite to each other; a first connecting structure which electrically connects the first substrate and the semiconductor chip, between the first substrate and the semiconductor chip; and a coil structure which includes a plurality of conductive layers, and is placed in at least one of the first substrate, the second substrate and the semiconductor chip, in which the first connecting structure includes first and second bumps spaced apart from each other in a horizontal direction, the coil structure includes first and second coil structures spaced apart from each other in the horizontal direction, one end of the first coil structure is electrically connected to the first bump, and one end of the second coil structure is electrically connected to the second bump.

### BRIEF DESCRIPTION OF THE DRAWINGS

Example implementations will be more clearly understood from the following descriptions, taken in conjunction with the accompanying drawings.

FIG. 1 schematically shows an example of a semiconductor package according to some implementations.

FIGS. 2 and 3 are diagrams showing examples of a coil structure configured to be included in a semiconductor package according to some implementations.

FIGS. 4 and 5 are diagrams showing examples of a coil structure configured to be included in a semiconductor package according to some implementations.

FIGS. 6 and 7 are diagrams showing examples of a coil structure configured to be included in a semiconductor package according to some implementations.

FIGS. 8 and 9 are diagrams showing examples of a coil structure configured to be included in a semiconductor package according to some implementations.

FIGS. 10 to 13 are schematic diagrams showing an example of a circuit to which a coil structure is applied according to some implements.

FIGS. 14 and 15 are diagrams showing examples of a coil structure configured to be included in a semiconductor package according to some implementations.

FIGS. 16 and 17 are diagrams showing examples of a coil structure configured to be included in a semiconductor package according to some implementations.

FIG. 18 is a schematic diagram showing an example of a circuit to which a coil structure is applied according to some implementations.

FIG. 19 is a diagram schematically showing an example of a semiconductor package according to some implementations.

FIGS. 20 and 21 are diagrams showing examples of a coil structure configured to be included in a semiconductor package according to some implementations.

FIGS. 22 and 23 are diagrams showing examples of a coil structure configured to be included in a semiconductor package according to some implementations.

FIG. 24 is a diagram showing an example of a coil structure configured to be included in a semiconductor package according to some implementations.

### DETAILED DESCRIPTION

Although terms, such as first and second, are used to describe various elements or components in the present specification, these elements or components are not limited by these terms. These terms are used to distinguish a single clement or component from other elements or components. Accordingly, a first element or component referred to below may be a second clement or component within the present disclosure.

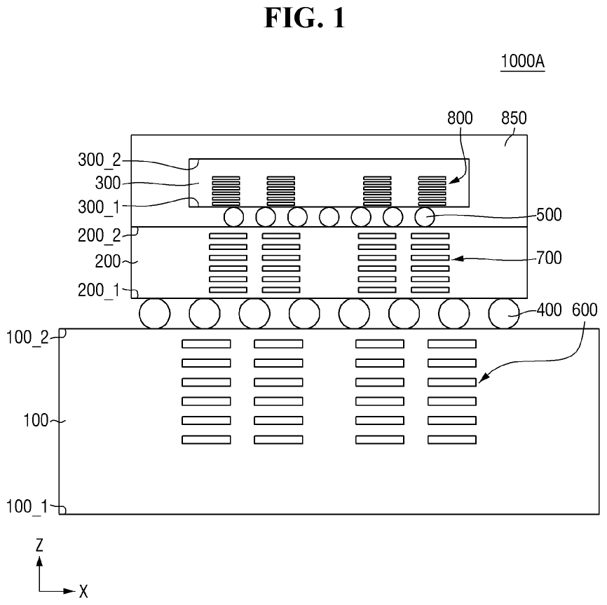

An example of a charging integrated circuit and an electronic device including the same according to some implementations will be described below with reference to FIGS. 1 to 3.

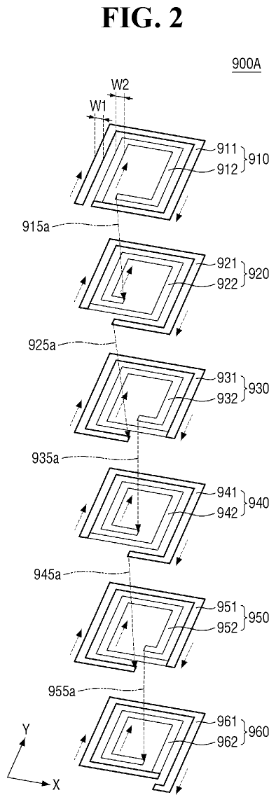

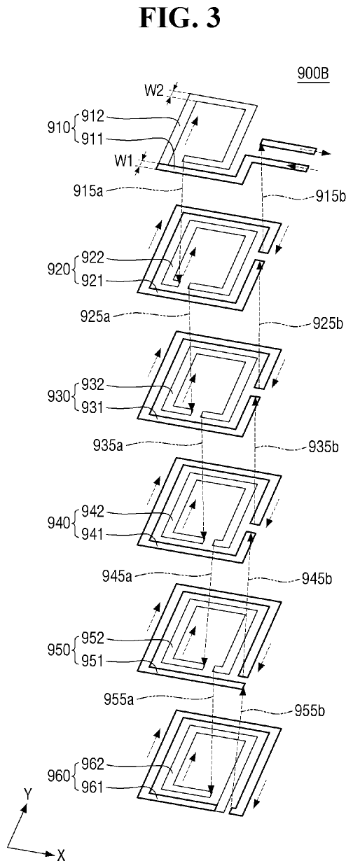

FIG. 1 is a diagram that schematically shows an example of semiconductor package according to some implementations. FIGS. 2 and 3 are diagrams showing an example of a coil structure configured to be included in a semiconductor package according to some implementations.

In FIG. 1, a semiconductor package 1000A according to some implementations may include a first substrate 100, a second substrate 200, a semiconductor chip 300, a first connecting structure 400, a second connecting structure 500, a first conductive structure 600, a second conductive structure 700, a third conductive structure 800, and a mold layer 850.

The first substrate 100 may be, for example, a printed circuit substrate (PCB) or a ceramic substrate. However, in some implementations, the first substrate 100 is not limited thereto. When the first substrate 100 is a printed circuit board, the first substrate 100 may be made up of at least one material selected from phenol resin, epoxy resin, and polyimide. The first substrate 100 may include, for example, at least one material selected from FR-4, tetrafunctional epoxy, polyphenylene ether, epoxy/polyphenylene oxide, BT (bismaleimide triazine), thermount, cyanate ester, polyimide, and liquid crystal polymer. Additionally, the surface of the first substrate 100 may be covered with solder resist.

A first conductive structure 600 may be placed inside the first substrate 100, and may include a wiring layer and a via for connecting the wiring layer. The first conductive structure 600 may be electrically connected to a second conductive structure 700 of the second substrate 200, which will be described later, through the first connecting structure 400. Although FIG. 1 shows that the first conductive structure 600 has six layers, in some implementations, it is not limited thereto. The first conductive structure 600 may include, for example, conductive metal materials, such as, but not limited to, copper (Cu) and titanium (Ti).

The first substrate 100 may include a first side 100_1 and a second side 100_2 that are opposite to each other. The first side 100_1 and the second side 100_2 may be a lower side and an upper side of the first substrate 100, respectively. The first side 100_1 and the second side 100_2 may extend in a first direction X and a second direction Y, respectively.

In some implementations, each of the first direction X and the second direction Y may indicate directions that are parallel to the first side 100_1 and the second side 100_2 and intersect each other. A third direction Z is a direction perpendicular to each of the first direction X and the second direction Y, and may indicate a direction in which a second substrate 200 and a semiconductor chip 300, which will be described later, are stacked. The first direction X and the second direction Y may each indicate a horizontal direction, and the third direction Z may indicate a vertical direction.

The second substrate 200 may be formed on the basis of a ceramic substrate, a PCB, an organic substrate, an interposer substrate, etc. Further, the second substrate 200 may be formed on the basis of an active wafer, such as a silicon wafer. The second substrate 200 may include an insulating material, for example, thermosetting resin such as epoxy resin, or thermoplastic resin such as polyimide, and may further include an inorganic filler. Further, the second substrate 200 may include prepreg, ABF (Ajinomoto Build-up Film), FR-4, BT (Bismalcimide Triazine) resin, PID (Photo Imageable Dielectric) resin, or the like, and may further include an inorganic filler.

The second substrate 200 may be placed on the first substrate 100. The second substrate 200 may be mounted on the second side 100_2 of the first substrate 100 through the first connecting structure 400.

A second conductive structure 700 may be placed inside the second substrate 200, and may include a wiring layer and a via for connecting the wiring layer. Although FIG. 1 shows that the second conductive structure 700 has six layers, the number of layers is not limited thereto. The second conductive structure 700 may include conductive metal materials, such as, but not limited to, copper (Cu) and titanium (Ti).

The second substrate 200 may include a third side 200_1 and a fourth side 200_2 that are opposite to each other. The third side 200_1 and the fourth side 200_2 may be a lower side and an upper side of the second substrate 200, respectively. The third side 200_1 and the fourth side 200_2 may extend in the first direction X and the second direction Y, respectively.

The semiconductor chip 300 may be placed on the second substrate 200. The semiconductor chip 300 may be mounted on the fourth side 200_2 of the second substrate 200 through a second connecting structure 500.

A third conductive structure 800 may be placed inside the semiconductor chip 300, and may include a wiring layer and a via for connecting the wiring layer. The third conductive structure 800 may be electrically connected to the second conductive structure 700 through the second connecting structure 500. Although FIG. 1 shows that the third conductive structure 800 has six layers, the number of layers is not limited thereto. The third conductive structure 800 may include conductive metal materials, such as, but not limited to, copper (Cu) and titanium (Ti).

The semiconductor chip 300 may include a fifth side 300_1 and a sixth side 600_2 that are opposite to each other. The fifth side 300_1 and the sixth side 600_2 may be a lower side and an upper side of the semiconductor chip 300, respectively. The fifth side 300_1 and the sixth side 600_2 may extend in the first direction X and the second direction Y, respectively. In some implementations, the fifth side 300_1 of the semiconductor chip 300 may indicate an active side.

The first connecting structure 400 may be placed between the second side 100_2 of the first substrate 100 and the third side 200_1 of the second substrate 200. The first connecting structure 400 may be a solder bump or a solder ball. The first connecting structure 400 may be placed between the first substrate 100 and the second substrate 200 to electrically connect the first substrate 100 and the second substrate 200.

The first connecting structure 400 may include, for example, at least one of tin (Sn), indium (In), lead (Pb), zinc (Zn), nickel (Ni), gold (Au), silver (Ag), copper (Cu), antimony (Sb), bismuth (Bi), and a combination thereof, but it is not limited thereto.

The second connecting structure 500 may be placed between the fourth side 200_2 of the second substrate 200 and the fifth side 300_1 of the semiconductor chip 300. The second connecting structure 500 may be a solder bump or a solder ball. The second connecting structure 500 may be placed between the second substrate 200 and the semiconductor chip 300 to electrically connect the second substrate 200 and the semiconductor chip 300.

The second connecting structure 500 may include, for example, at least one of tin (Sn), indium (In), lead (Pb), zinc (Zn), nickel (Ni), gold (Au), silver (Ag), copper (Cu), antimony (Sb), bismuth (Bi), and a combination thereof, but it is not limited thereto.

The first substrate 100, the second substrate 200, and the semiconductor chip 300 may be connected in series through the first connecting structure 400 and the second connecting structure 500.

The mold layer 850 may be placed on the fourth side 200_2 of the second substrate 200. The mold layer 850 may be formed to integrally wrap at least a part of the fifth side 300_1 of the semiconductor chip 300, the side face of the semiconductor chip 300, the sixth side 300_2 of the semiconductor chip 300, and the side face of the second connecting structure 500. The mold layer 850 may include, for example, an insulating material, such as, but not limited to, epoxy molding compound (EMC) or two or more kinds of silicon hybrid materials.

In FIGS. 2 and 3, a semiconductor package according to some implementations may include a coil structure connected in a single-ended manner.

In FIG. 1, the semiconductor package according to some implementations may include a coil structure 900A, as shown in FIG. 2. For example, the coil structure 900A may be placed on at least one of the first substrate 100, the second substrate 200, and the semiconductor chip 300., The coil structure 900A may be at least one of the first conductive structure 600, the second conductive structure 700, and the third conductive structure 800 of FIG. 1.

The coil structure 900A may include first to sixth coil parts 910 to 960 that are stacked sequentially, and 1a-th to 5a-th vias 915a to 955a that electrically connect the first to sixth coil parts 910 to 960.

A first coil part 910 may include a first_1 coil pattern 911, and a first_2 coil pattern 912 inside the first_1 coil pattern 911. An electrical signal may be input from one end of the first_1 coil pattern 911. The other end of the first_1 coil pattern 911 may be connected to one end of the first_2 coil pattern 912. The other end of the first_2 coil pattern 912 may be connected to a second coil part 920 through a 1a-th via 915a. Each of the first_1 coil pattern 911 and the first_2 coil pattern 912 may form at least one turn.

The second coil part 920 may include a second_1 coil pattern 921, and a second_2 coil pattern 922 inside the second_1 coil pattern 921. One end of the second_2 coil pattern 922 may be connected to the other end of the first_2 coil pattern 912 through the 1a-th via 915a, and the other end of the second_2 coil pattern 922 may be connected to one end of the second_1 coil pattern 921. The other end of the second_1 coil pattern 921 may be connected to a third coil part 930 through the 2a-th via 925a. The second_2 coil pattern 922 may form at least one turn.

The third coil part 930 may include a third_1 coil pattern 931, and a third_2 coil pattern 932 inside the third_1 coil pattern 931. One end of the third_1 coil pattern 931 may be connected to the other end of the second_1 coil pattern 9212 through the 2a-th via 925a, and the other end of the third_1 coil pattern 931 may be connected to one end of the third_2 coil pattern 932. The other end of the third_2 coil pattern 932 may be connected to a fourth coil part 940 through a 3a-th via 935a. The third_2 coil pattern 932 may form at least one turn.

The fourth coil part 940 may include a fourth_1 coil pattern 941, and a fourth_2 coil pattern 942 inside the fourth_1 coil pattern 941. One end of the fourth_2 coil pattern 942 may be connected to the other end of the third_2 coil pattern 932 through the 3a-th via 935a, and the other end of the fourth_2 coil pattern 942 may be connected to one end of the fourth_1 coil pattern 941. The other end of the fourth_1 coil pattern 941 may be connected to a fifth coil part 950 through a 4a-th via 945a. The fourth_2 coil pattern 942 may form at least one turn.

The fifth coil part 950 may include a fifth_1 coil pattern 951, and a fifth_2 coil pattern 952 inside the fifth_1 coil pattern 951. One end of the fifth_1 coil pattern 951 may be connected to the other end of the fourth_1 coil pattern 941 through the 4a-th via 945a, and the other end of the fifth_1 coil pattern 951 may be connected to one end of the fifth_2 coil pattern 952. The other end of the fifth_2 coil pattern 952 may be connected to a sixth coil part 960 through a 5a-th via 955a. The fifth_2 coil pattern 952 may form at least one turn.

The sixth coil part 960 may include a sixth_1 coil pattern 961, and a sixth_2 coil pattern 962 inside the sixth_1 coil pattern 961. One end of the sixth_2 coil pattern 962 may be connected to the other end of the fifth_2 coil pattern 952 through the 5a-th via 955a, and the other end of the sixth_2 coil pattern 962 may be connected to one end of the sixth_1 coil pattern 961. An electrical signal may be output from the other end of the sixth_1 coil pattern 961. Each of the sixth_1 coil pattern 961 and the sixth_2 coil pattern 962 may form at least one turn.

When the coil structure 900A is the first conductive structure 600, one end of the coil structure 900A, that is, one end of the first_1 coil pattern 911, may be electrically connected to the first connecting structure 400, and the other end of the coil structure 900A, that is, the other end of the sixth_1 coil pattern 961, may be electrically connected to ground adjacent to the first side 100_1 of the first substrate 100.

When the coil structure 900A is the second conductive structure 700, one end of the coil structure 900A, that is, one end of the first_1 coil pattern 911, may be electrically connected to the second connecting structure 500, and the other end of the coil structure 900A, that is, the other end of the sixth_1 coil pattern 961, may be electrically connected to the ground adjacent to the third side 200_1 of the second substrate 200.

When the coil structure 900A is the third conductive structure 800, one end of the coil structure 900A, that is, one end of the first_1 coil pattern 911, may be electrically connected to the wiring layer inside the semiconductor chip 300, and the other end of the coil structure 900A, that is, the other end of the sixth_1 coil pattern 961, may be electrically connected to the ground GND adjacent to the sixth side 300_2 of the semiconductor chip 300.

In FIG. 1, the semiconductor package according to some implementations may include a coil structure 900B, as shown in FIG. 3.

The coil structure 900B may be placed on at least one of the first substrate 100, the second substrate 200, and the semiconductor chip 300. The coil structure 900B may be at least one of the first conductive structure 600, the second conductive structure 700, and the third conductive structure 800.

The coil structure 900B may include first to sixth coil parts 910 to 960 which are stacked sequentially, and 1a-th to 5a-th vias 915a to 955a and 1b-th to 5b-th vias 915b to 955b that electrically connect the first to sixth coil parts 910 to 960.

A first coil part 910 may include a first_1 coil pattern 911, and a first_2 coil pattern 912 inside the first_1 coil pattern 911. An electrical signal may be input from one end of the first_1 coil pattern 911. The first_1 coil pattern 911 may be connected to one end of the first_2 coil pattern 912. The other end of the first_2 coil pattern 912 may be connected to a second coil part 920 through the 1a-th via 915a. The first_2 coil pattern 912 may form at least one turn.

The second coil part 920 may include a second_1 coil pattern 921, and a second_2 coil pattern 922 inside the second_1 coil pattern 921. One end of the second_2 coil pattern 922 may be connected to the other end of the first_2 coil pattern 912 through the 1a-th via 915a, and the other end of the second_2 coil pattern 922 may be connected to the third coil part 930. The second_1 coil pattern 921 and the second_2 coil pattern 922 may form at least one turn.

The third coil part 930 may include a third_1 coil pattern 931, and a third_2 coil pattern 932 inside the third_1 coil pattern 931. One end of the third_2 coil pattern 932 may be connected to the other end of the second_2 coil pattern 922 through the 2a-th via 925a, and the other end of the third_2 coil pattern 932 may be connected to the fourth coil part 940. The third_1 coil pattern 931 and the third_2 coil pattern 932 may form at least one turn.

The fourth coil part 940 may include a fourth_1 coil pattern 941, and a fourth_2 coil pattern 942 inside the fourth_1 coil pattern 941. One end of the fourth_2 coil pattern 942 may be connected to the other end of the third_2 coil pattern 932 through the 3a-th via 935a, and the other end of the fourth_2 coil pattern 942 may be connected to the fifth coil part 950. The fourth_1 coil pattern 941 and the fourth_2 coil pattern 942 may form at least one turn.

The fifth coil part 950 may include a fifth_1 coil pattern 951, and a fifth_2 coil pattern 952 inside the fifth_1 coil pattern 951. One end of the fifth_2 coil pattern 952 may be connected to the other end of the fourth_2 coil pattern 942 through the 4a-th via 945a, and the other end of the fifth_2 coil pattern 952 may be connected to a sixth coil part 960. The fifth_1 coil pattern 951 and the fifth_2 coil pattern 952 may form at least one turn.

The sixth coil part 960 may include a sixth_1 coil pattern 961, and a sixth_2 coil pattern 962 inside the sixth_1 coil pattern 961. One end of the sixth_2 coil pattern 962 may be connected to the other end of the fifth_2 coil pattern 952 through the 5a-th via 955a, and the other end of the sixth_2 coil pattern 962 may be connected to one end of the sixth_1 coil pattern 961. The sixth_1 coil pattern 961 and the sixth_2 coil pattern 962 may form at least one turn.

The other end of the sixth_1 coil pattern 961 may be connected to one end of the fifth_1 coil pattern 951 through the 5b-th via 955b. The other end of the fifth_1 coil pattern 951 may be connected to one end of the fourth_1 coil pattern 941 through the 4b-th via 945b. The other end of the fourth_1 coil pattern 941 may be connected to one end of the third_1 coil pattern 931 through the 3b-th via 935b. The other end of the third_1 coil pattern 931 may be connected to one end of the second_1 coil pattern 921 through the 2b-th via 925b. The other end of the second_1 coil pattern 921 may be connected to one end of the first_1 coil pattern 911 through the 1b-th via 915b. An electrical signal may be output from the other end of the first_1 coil pattern 911.

When the coil structure 900B is the first conductive structure 600, one end of the coil structure 900B, that is, one end of the first_1 coil pattern 911, may be electrically connected to the first connecting structure 400, and the other end of the coil structure 900B, that is, the other end of the first_1 coil pattern 911, may be electrically connected to the ground adjacent to the second side 100_2 of the first substrate 100.

When the coil structure 900B is the second conductive structure 700, one end of the coil structure 900B, that is, one end of the first_1 coil pattern 911, may be electrically connected to the second connecting structure 500, and the other end of the coil structure 900B, that is, the other end of the first_1 coil pattern 911, may be electrically connected to the ground adjacent to the fourth side 200_2 of the second substrate 200.

When the coil structure 900A is the third conductive structure 800, one end of the coil structure 900B, that is, one end of the first_1 coil pattern 911, may be electrically connected to the wiring layer inside the semiconductor chip 300, and the other end of the coil structure 900B, that is, the other end of the first_1 coil pattern 911, may be electrically connected to the ground adjacent to the fifth side 300_1 of the semiconductor chip 300.

Quality factors based on an interrelationship between inductance, parasitic capacitance, and resistance components of a stacked inductor are called Q characteristics (quality factors). In general, when the Q characteristics in the inductor are improved, it possible to reduce the number of layers of the stacked inductor and increase the degree of design freedom depending on the spatial placement. Furthermore, when the number of stacked conductive layers is large, the capacitance value becomes small, and the self-resonant frequency may be increased.

Since the semiconductor package including the coil structures 900A and 900B according to some implementations include the stacked inductor, it is possible to reduce a loss due to metal components (metal loss) or eddy current loss, and increase the Q value. In particular, the semiconductor package according to some implementations are applicable to electronic devices that include a radio frequency integrated circuit (RFIC) with high quality Q values.

In FIGS. 2 and 3, a width W1 of the first_1 coil pattern 911 placed outside the first coil part 910 may be substantially equal to a width W2 of the first_2 coil pattern 912 placed inside. Similarly, a width of the second_1 coil pattern 921 of the second coil part 920 may be substantially equal to a width of the second_2 coil pattern 922, a width of the third_1 coil pattern 931 of the third coil part 930 may be substantially equal to a width of the third_2 coil pattern 932, a width of the fourth_1 coil pattern 941 of the fourth coil part 940 may be substantially equal to a width of the fourth_2 coil pattern 942, a width of the fifth_1 coil pattern 951 of the fifth coil part 950 may be substantially equal to a width of the fifth_2 coil pattern 952, and a width of the sixth_1 coil pattern 961 of the sixth coil part 960 may be substantially equal to a width of the sixth_2 coil pattern 962.

In some implementations, the width W1 of the first_1 coil pattern 911 may be greater than the width W2 of the first_2 coil pattern 912. Similarly, the width of the second_1 coil pattern 921 of the second coil part 920 may be greater than the width of the second_2 coil pattern 922, the width of the third_1 coil pattern 931 of the third coil part 930 may be greater than the width of the third_2 coil pattern 932, the width of the fourth_1 coil pattern 941 of the fourth coil part 940 may be greater than the width of the fourth_2 coil pattern 942, the width of the fifth_1 coil pattern 951 of the fifth coil part 950 may be greater than the width of the fifth_2 coil pattern 952, and the width of the sixth_1 coil pattern 961 of the sixth coil part 960 may be greater than the width of the sixth_2 coil pattern 962.

In some implementations, the width of the coil pattern of the outer coil part may be widened and the width of the coil pattern of the inner coil part may be widened to obtain improved Q characteristics. Specifically, when the width of the coil pattern of the outer coil part is widened, the loss due to the metal component may be reduced to obtain improved Q characteristics, and when the width of the coil pattern of the inner coil part is narrowed, the inductance value may be increased.

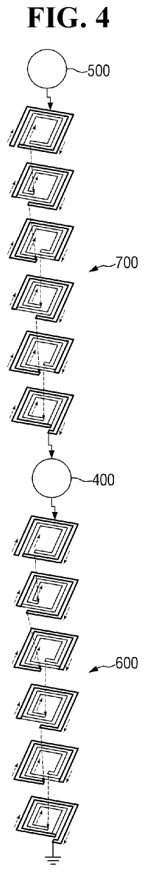

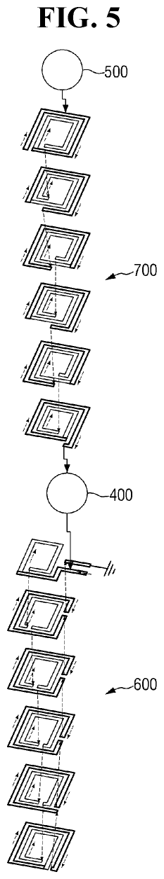

FIGS. 4 and 5 are diagrams showing examples of a coil structure included in a semiconductor package according to some implementations. For efficiency, the following description focuses on the differences from the semiconductor packages and coil structures shown in FIGS. 1 to 3.

In FIG. 4, the semiconductor package includes the first conductive structure 600 placed inside the first substrate 100, and the second conductive structure 700 placed inside the second substrate 100.

One end of the first conductive structure 600 may be electrically connected to the first connecting structure 400, and the other end of the first conductive structure 600 may be electrically connected to ground adjacent to the first side 100_1 of the first substrate 100.

One end of the second conductive structure 700 may be electrically connected to the second connecting structure 500, and the other end of the second conductive structure 700 may be electrically connected to the first connecting structure 400.

The coil structure 900A described with respect to FIG. 2 may be similarly applied to each of the first conductive structure 600 and the second conductive structure 700.

In FIG. 5, the semiconductor package includes the first conductive structure 600 placed inside the first substrate 100, and the second conductive structure 700 placed inside the second substrate 100. One end of the first conductive structure 600 may be electrically connected to the first connecting structure 400, and the other end of the first conductive structure 600 may be electrically connected to ground adjacent to the second side 100_2 of the first substrate 100.

One end of the second conductive structure 700 may be electrically connected to the second connecting structure 500, and the other end of the second conductive structure 700 may be electrically connected to the first connecting structure 400.

The coil structure 900B in FIG. 3 may be similarly applied to the first conductive structure 600. The coil structure 900A in FIG. 2 may be similarly applied to the second conductive structure 700.

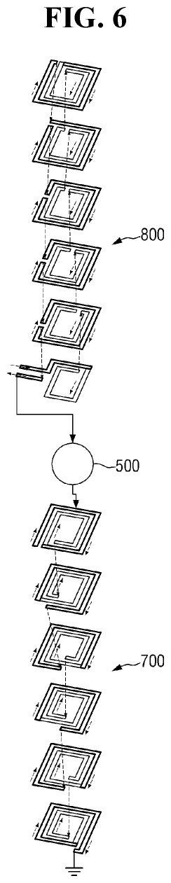

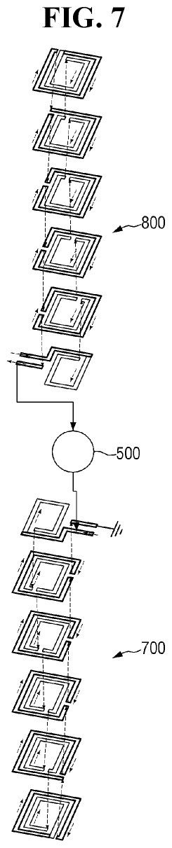

FIGS. 6 and 7 are diagrams showing examples of a coil structure included in a semiconductor package according to some implementations. For efficiency, the following description focuses on differences from the semiconductor package and coil structures shown in FIGS. 1 to 5.

In FIG. 6, the semiconductor package includes the second conductive structure 700 placed inside the second substrate 200, and the third conductive structure 800 placed inside the semiconductor chip 300.

One end of the second conductive structure 700 may be electrically connected to the second connecting structure 500, and the other end of the second conductive structure 700 may be electrically connected to ground adjacent to the third side 200_1 of the second substrate 200.

One end of the third conductive structure 800 may be electrically connected to the wiring layer inside the semiconductor chip 300, and the other end of the third conductive structure 800 may be electrically connected to the second connecting structure 500.

The explanation of the coil structure 900A shown in FIG. 2 may be similarly applied to the second conductive structure 700. The explanation of the coil structure 900B shown in FIG. 3 may be similarly applied to the third conductive structure 800.

In FIG. 7, a semiconductor package according to some implementations includes the second conductive structure 700 placed inside the second substrate 200, and the third conductive structure 800 placed inside the semiconductor chip 300. One end of the second conductive structure 700 may be electrically connected to the second connecting structure 500, and the other end of the second conductive structure 700 may be electrically connected to ground adjacent to the fourth side 200_2 of the second substrate 200. Additionally, one end of the third conductive structure 800 may be electrically connected to the wiring layer inside the semiconductor chip 300, and the other end of the third conductive structure 800 may be electrically connected to the second connecting structure 500.

The explanation of the coil structure 900B in FIG. 3 may be similarly applied to each of the second conductive structure 700 and the third conductive structure 800.

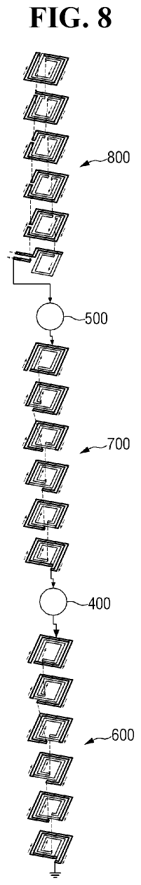

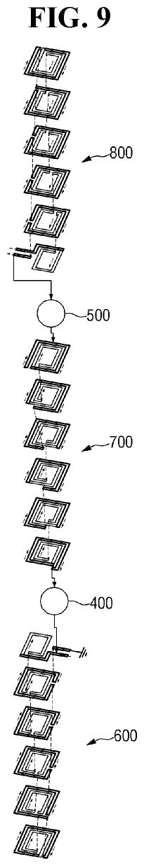

FIGS. 8 and 9 are diagrams showing examples of a coil structure included in a semiconductor package according to some implementations. For efficiency, the explanation will focus on differences from the semiconductor package and coil structures shown in FIGS. 1 to 7.

In FIG. 8, a semiconductor package according to some implementations includes the first conductive structure 600 placed inside the first substrate 100, the second conductive structure 700 placed inside the second substrate 200, and the third conductive structure 800 placed inside the semiconductor chip 300.

One end of the first conductive structure 600 may be electrically connected to the first connecting structure 400, and the other end of the first conductive structure 600 may be electrically connected to ground adjacent to the first side 100_1 of the first substrate 100. Additionally, one end of the second conductive structure 700 may be electrically connected to the second connecting structure 500, and the other end of the second conductive structure 700 may be electrically connected to the first connecting structure 400. Furthermore, one end of the third conductive structure 800 may be electrically connected to the wiring layer inside the semiconductor chip 300, and the other end of the third conductive structure 800 may be electrically connected to the second connecting structure 500.

The explanation of the coil structure 900A in FIG. 2 may be similarly applied to each of the first conductive structure 600 and the second conductive structure 700. The explanation of the coil structure 900B in FIG. 3 may be similarly applied to the third conductive structure 800.

In FIG. 9, a semiconductor package according to some implementations includes the first conductive structure 600 placed inside the first substrate 100, the second conductive structure 700 placed inside the second substrate 100, and the third conductive structure 800 placed inside the semiconductor chip 300.

One end of the first conductive structure 600 may be electrically connected to the first connecting structure 400, and the other end of the first conductive structure 600 may be electrically connected to ground adjacent to the second side 100_2 of the first substrate 100. Additionally, one end of the second conductive structure 700 may be electrically connected to the second connecting structure 500, and the other end of the second conductive structure 700 may be electrically connected to the first connecting structure 400. Furthermore, one end of the third conductive structure 800 may be electrically connected to the wiring layer inside the semiconductor chip 300, and the other end of the third conductive structure 800 may be electrically connected to the second connecting structure 500.

The explanation of the coil structure 900B in FIG. 3 may be similarly applied to the second conductive structure 700. The explanation of the coil structure 900A in FIG. 2 may be similarly applied to each of the first conductive structure 600 and the third conductive structure 800.

When using a semiconductor package that includes the coil structure according to various implementations described herein, an increase in the number of stacked conductive layers may correspond to an increase in the inductance value, such that the semiconductor package is applicable to an electronic device including a power management integrated circuit (PMIC).

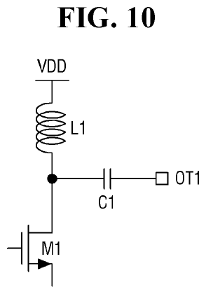

FIGS. 10 to 13 are schematic diagrams showing an example of circuit to which a coil structure is applied.

In FIG. 10, according to some implementations, a circuit includes a first inductor L1, a first capacitor C1, and a first transistor M1. The first capacitor C1 may be connected to a first output terminal OT1. The first capacitor C1 may be a decoupling capacitor that serves to block a power supply voltage VDD. The first inductor L1 may be connected to one end of the first transistor M1.

The first inductor L1 may correspond to each of the coil structures 900A and 900B in FIGS. 1 to 3, or the coil structure in FIGS. 4 to 9.

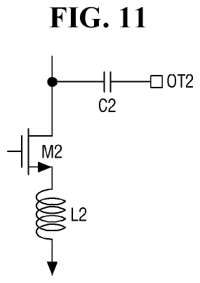

In FIG. 11, according to some implementations, a circuit includes a second inductor L2, a second capacitor C2, and a second transistor M2. The second capacitor C2 may be connected to the second output terminal OT2. The second inductor L2 may be connected to one end of the second transistor M2.

The second inductor L2 may correspond to each of the coil structures 900A and 900B in FIGS. 1 to 3, or the coil structures in FIGS. 4 to 9.

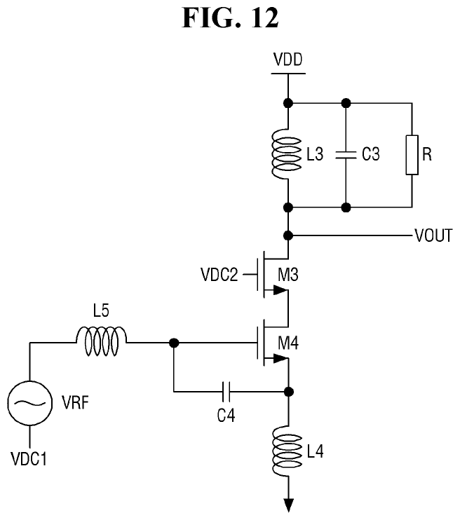

In FIG. 12, according to some implementations, a circuit may include a third inductor L3, a fourth inductor L4, a fifth inductor L5, a third transistor M3, a fourth transistor M4, a fourth capacitor C3, a fourth capacitor C4, and a resistor R.

The third inductor L3, the third capacitor C3, and the resistor R may be connected in parallel with each other. The third capacitor C3 and the resistor R may be used to determine the self-resonant frequency.

The third transistor M3 and the fourth transistor M4 may be placed between the third inductor L3 and the fourth inductor L4. In some implementations, the third inductor L3 of FIG. 12 corresponds to the first inductor L1 in FIG. 10, and the fourth inductor L4 of FIG. 12 may correspond to the second inductor L2 in FIG. 11.

The third to fifth inductors L3, L4, and L5 may each correspond to the coil structures 900A and 900B in FIGS. 1 to 3, or the coil structures in FIGS. 4 to 9, respectively.

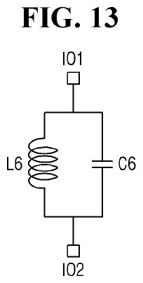

In FIG. 13, according to some implementations, a circuit includes a sixth inductor L6 and a sixth capacitor C6 placed between first and second input/output terminals IO1 and IO2. In some implementations, the circuit may further include a resistor connected in parallel with the sixth inductor L6 and the sixth capacitor C6. Accordingly, the sixth capacitor C6 and the resistor may be used to determine the self-resonant frequency similarly to the third capacitor C3 and the resistor R in FIG. 12.

In some implementations, the circuits shown in FIGS. 10 to 13 are applicable to an electronic device including a low noise amplifier, a mixer, a power amplifier, and the like.

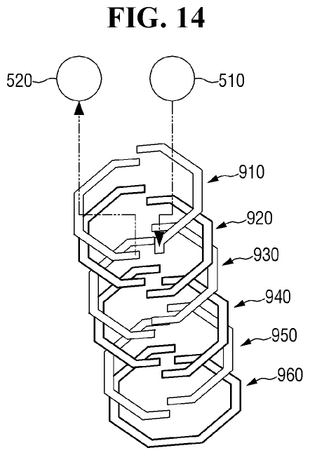

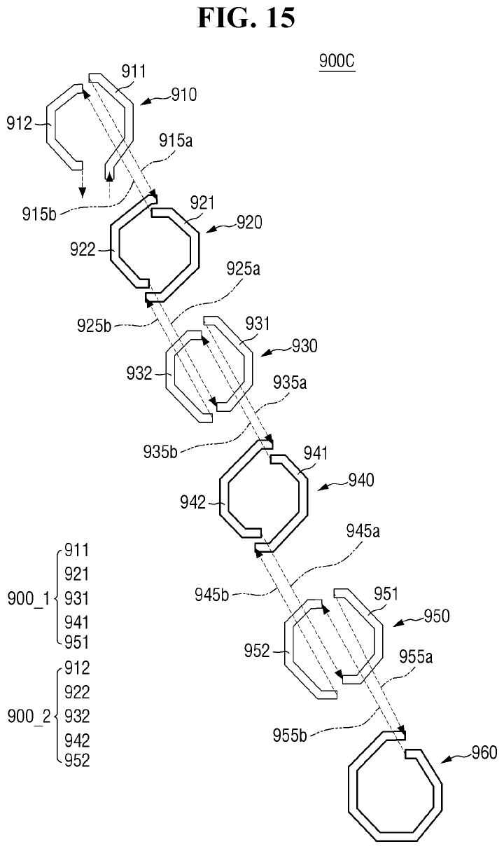

FIGS. 14 and 15 are diagrams showing examples of a coil structure configured to be included in a semiconductor package according to some implementations. FIG. 14 is a diagram showing an example of a coil structure and bumps configured to be included in a semiconductor package according to some implementations. For efficiency, the explanation will focus on differences from the semiconductor package and coil structures shown in FIGS. 1 to 9.

In FIGS. 14 to 18 and 24, a semiconductor package according to some implementations may include coil structures connected in a differential manner.

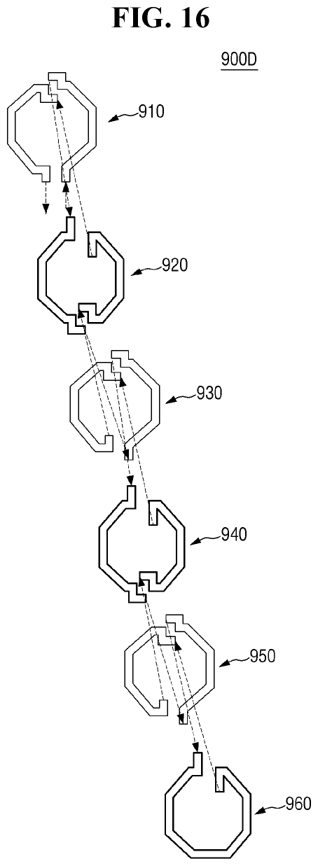

In FIGS. 1 and 16, according to some implementations, a second connecting structure (500 in FIG. 1) of the semiconductor package may include first and second bumps 510 and 520 spaced apart from each other in the first direction X.

Specifically, in FIGS. 1 and 15, according to some implementations, a coil structure 900C is placed inside the second substrate (200 in FIG. 1). The coil structure 900C may include first and second coil structures 900_1 and 900_2 spaced apart from each other in the first direction X. One end of the first coil structure 900_1 may be electrically connected to the first bump 510 of the second connecting structure (500 of FIG. 1), and one end of the second coil structure 900_2 may be electrically connected to the second bump 520 of the second connecting structure (500 in FIG. 1).

The coil structure 900C includes first to sixth coil parts 910 to 960 that are stacked sequentially, and 1a-th to 5a-th vias 915a to 955a and 1b-th to 5b-th vias 915b to 955b that electrically connect the first to sixth coil parts 910 to 960.

The first coil part 910 may include a first_1 coil pattern 911, and a first_2 coil pattern 912 spaced apart from the first_1 coil pattern 911 in the horizontal direction. One end of the first_1 coil pattern 911 may be connected to the first bump 510, and the other end of the first_1 coil pattern 911 may be connected to the second coil part 920 through the 1a-th via 915a. Each of the first_1 coil pattern 911 and the first_2 coil pattern 912 may form a turn less than one turn.

The second coil part 920 may include a second_1 coil pattern 921, and a second_2 coil pattern 922 spaced apart from the second_1 coil pattern 921 in the horizontal direction. The second_1 coil pattern 921 and the second_2 coil pattern 922 may be placed to correspond to the first_1 coil pattern 911 and the first_2 coil pattern 912, respectively. One end of the second_2 coil pattern 922 may be connected to the other end of the first_1 coil pattern 911 through the 1a-th via 915a, and the other end of the second_2 coil pattern 922 may be connected to the third coil part 930 through the 2a-th via 925a. Each of the second_1 coil pattern 921 and the second_2 coil pattern 922 may form a turn less than one turn.

The third coil part 930 may include a third_1 coil pattern 931, and a third_2 coil pattern 932 spaced apart from the third_1 coil pattern 931 in the horizontal direction. The third_1 coil pattern 931 and the third_2 coil pattern 932 may be placed to correspond to the second_1 coil pattern 921 and the second_2 coil pattern 922, respectively. One end of the third_1 coil pattern 931 may be connected to the other end of the second_2 coil pattern 922 through the 2a-th via 925a, and the other end of the third_1 coil pattern 931 may be connected to the fourth coil part 940 through the 3a-th via 935a. Each of the third_1 coil pattern 931 and the third_2 coil pattern 932 may form a turn less than one turn.

The fourth coil part 940 may include a fourth_1 coil pattern 941, and a fourth_2 coil pattern 942 spaced apart from the fourth_1 coil pattern 941 in the horizontal direction. The fourth_1 coil pattern 941 and the fourth_2 coil pattern 942 may be placed to correspond to the third_1 coil pattern 931 and the third_2 coil pattern 932, respectively. One end of the fourth_2 coil pattern 942 may be connected to the other end of the third_1 coil pattern 931 through the 3a-th via 935a, and the other end of the fourth_2 coil pattern 942 may be connected to the fifth coil part 950 through the 4a-th via 945a. Each of the fourth_1 coil pattern 941 and the fourth_2 coil pattern 942 may form a turn less than one turn.

The fifth coil part 950 may include a fifth_1 coil pattern 951, and a fifth_2 coil pattern 952 spaced apart from the fifth_1 coil pattern 951 in the horizontal direction. The fifth_1 coil pattern 951 and the fifth_2 coil pattern 952 may be placed to correspond to the fourth_1 coil pattern 941 and the fourth_2 coil pattern 942, respectively. One end of the fifth_1 coil pattern 951 may be connected to the other end of the fourth_2 coil pattern 942 through the 4a-th via 945a, and the other end of the fifth_1 coil pattern 951 may be connected to the sixth coil part 960 through the 5a-th via 955a. Each of the fifth_1 coil pattern 951 and the fifth_2 coil pattern 952 may form a turn less than one turn.

One end of the sixth coil part 960 may be connected to the other end of the fifth_1 coil pattern 951 through the 5a-th via 955a, and the other end of the sixth coil part 960 may be connected to the fifth coil part 950 through the 5b-th via 955b. The sixth coil part 960 may form at least one turn.

The other end of the sixth coil part 960 may be connected to one end of the fifth_2 coil pattern 952 through the 5b-th via 955b. The other end of the fifth_2 coil pattern 952 may be connected to one end of the fourth_1 coil pattern 941 through the 4b-th via 945b. The other end of the fourth_1 coil pattern 941 may be connected to one end of the third_2 coil pattern 932 through the 3b-th via 935b. The other end of the third_2 coil pattern 932 may be connected to one end of the second_1 coil pattern 921 through the 2b-th via 925b. The other end of the second_1 coil pattern 921 may be connected to one end of the first_2 coil pattern 912 through the 1b-th via 915b. The other end of the first_2 coil pattern 912 may be connected to the second bump 520.

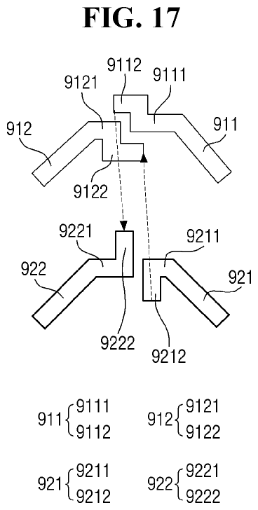

FIGS. 16 and 17 are diagrams showing examples of a coil structure configured to be included in a semiconductor package according to some implementations. For efficiency, the following description focuses on differences from the semiconductor package and coil structures shown in FIGS. 14 and 15.

In FIGS. 15-17, in some implementations, in a coil structure 900D, an end of a first coil structure (900_1 of FIG. 15) and an end of a second coil structure (900_2 of FIG. 15) may each include a plurality of folded parts.

In the first coil part 910, each of the end of the first_1 coil pattern (911 of FIG. 17) and the end of the first_2 coil pattern (912 of FIG. 17) may include a plurality of folded parts. For example, the end of the first_1 coil pattern (911 of FIG. 17) may include a first folded part (9111 of FIG. 17) and a second folded part (9112 of FIG. 17). The end of the first_2 coil pattern (912 of FIG. 17) may include a first folded part (9121 of FIG. 17) and a second folded part (9122 of FIG. 17). The end of the first_1 coil pattern (911 of FIG. 17) and the end of the first_2 coil pattern (912 of FIG. 17) may correspond to each other so that the first coil part 910 has a nearly circular shape through the plurality of folded parts.

In the second coil part 920, each of the end of the second_1 coil pattern (921 of FIG. 17) and the end of the second_2 coil pattern (922 of FIG. 17) may include a plurality of folded parts. The end of the second_1 coil pattern (921 of FIG. 17) may include a first folded part (9211 of FIG. 17) and a second folded part (9212 of FIG. 17). The end of the second_2 coil pattern (922 of FIG. 17) may include a first folded part (9221 of FIG. 17) and a second folded part (9222 of FIG. 17). The end of the second_1 coil pattern (921 of FIG. 17) and the end of the second_2 coil pattern (922 of FIG. 17) may correspond to each other so that the second coil part 920 has a nearly circular shape through the plurality of folded parts.

The first folded part (9111 of FIG. 17) of the first_1 coil pattern (911 of FIG. 17) and the first folded part (9121 of FIG. 17) of the first_2 coil pattern (912 of FIG. 17) may protrude to face in opposite directions to each other. The second folded part (9112 of FIG. 17) of the first_1 coil pattern (911 of FIG. 17) and the second folded part (9122 of FIG. 17) of the first_2 coil pattern (912 of FIG. 17) may protrude to face in opposite directions to each other.

The second folded part (9212 of FIG. 17) of the second_1 coil pattern (921 of FIG. 17) and the second folded part (9222 of FIG. 17) of the second_2 coil pattern (922 of FIG. 17) may protrude to face in opposite directions to each other.

The plurality of folded parts of the first coil part (910 of FIG. 17) may be similarly applied to each of the third coil part (930 of FIG. 15) and the fifth coil part (950 of FIG. 15). Furthermore, the plurality of folded parts of the second coil part (920 of FIG. 17) may be similarly applied to the fourth coil part (940 of FIG. 15) and the sixth coil part (960 of FIG. 15).

In some implementations, the semiconductor package including the coil structures 900C and 900D includes a stacked inductor, and therefore may reduce loss due to metal components (metal loss) or eddy current loss, and may increase the Q value.

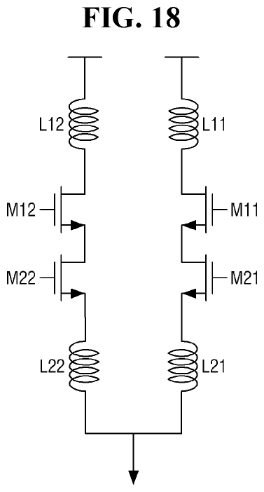

FIG. 18 is a schematic diagram showing an example of a circuit to which a coil structure is applied according to some implementations.

In FIG. 18, in some implementations, a circuit includes a first_1 inductor L11, a first_2 inductor L12, a second_1 inductor L21, a second_2 inductor L22, a first_1 transistor M11, a first_2 transistor M12, a second_1 transistor M21, and a second_2 transistor M22.

The first_1 inductor L11 and the second_1 inductor L21 may be connected in series. The first_1 transistor M11 and the second_1 transistor M21 may be placed between the first_1 inductor L11 and the second_1 inductor L21.

The first_2 inductor L12 and the second_2 inductor L22 may be connected in series. The first_2 transistor M12 and the second_2 transistor M22 may be placed between the first_2 inductor L12 and the second_2 inductor L22.

For example, the first_1 inductor L11 and the second_1 inductor L21 may each correspond to the coil structure 900_1 in FIGS. 14 to 17. The first_2 inductor L12 and the second_2 inductor L22 may each correspond to the coil structure 900_2 in FIGS. 14 to 17. However, the present disclosure is not limited thereto.

In some implementations, the circuit is applicable to electronic devices including a low noise amplifier, a mixer, a power amplifier, a voltage controlled oscillator, and the like.

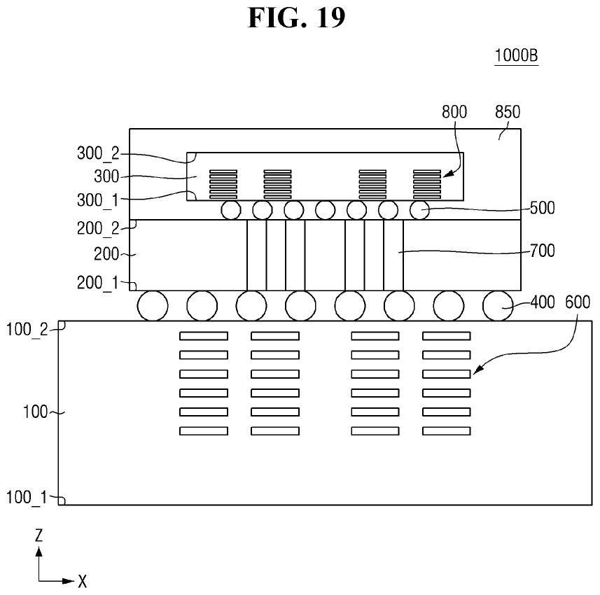

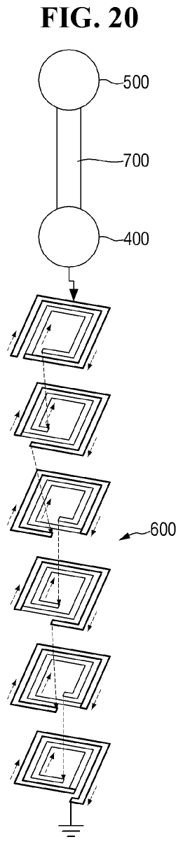

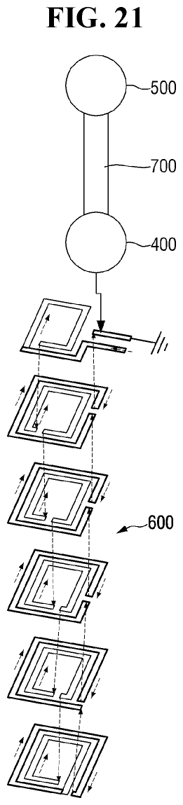

FIG. 19 is a diagram that schematically showing an example of a semiconductor package according to some implementations. FIGS. 20 and 21 are diagrams showing examples of a coil structure configured to be included in a semiconductor package according to some implementations. For efficiency, the following description focuses on differences from the semiconductor package and coil structures shown in FIGS. 1 to 9 and 14 to 17.

In FIG. 19, in some implementations, a semiconductor package 1000B includes a through via structure 700. For example, the second conductive structure 700 in FIG. 1 may be in the form of a Through Silicon Via (TSV).

In FIG. 20, in some implementations, a semiconductor package includes a first conductive structure 600 placed inside the first substrate 100, and a through via structure 700 placed inside the second substrate 200. One end of the first conductive structure 600 may be electrically connected to the first connecting structure 400. The other end of the first conductive structure 600 may be connected to ground adjacent to the first side 100_1 of the first substrate 100.

The through via structure 700 may be placed between the first connecting structure 400 and the second connecting structure 500. The through via structure 700 may be electrically connected to the first conductive structure 600.

The coil structure 900A in FIG. 2 may be similarly applied to the first conductive structure 600.

In FIG. 21, according to some implementations, a semiconductor package includes the first conductive structure 600 placed inside the first substrate 100, and the through via structure 700 placed inside the second substrate 200. One end of the first conductive structure 600 may be electrically connected to the first connecting structure 400. The other end of the first conductive structure 600 may be connected to ground adjacent to the second side 100_2 of the first substrate 100

The through via structure 700 may be placed between the first connecting structure 400 and the second connecting structure 500. The through via structure 700 may be electrically connected to the first conductive structure 600.

The coil structure 900B in FIG. 3 may be similarly applied to the first conductive structure 600.

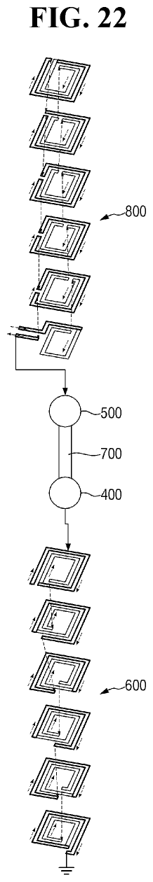

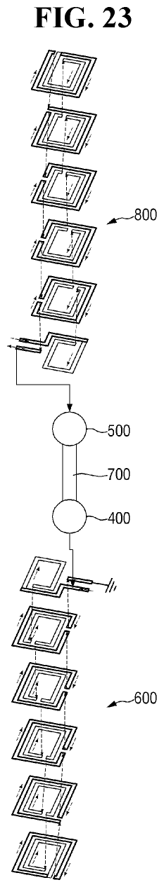

FIGS. 22 and 23 are diagrams showing examples of a coil structure configured to be included in a semiconductor package according to some implementations. For efficiency, the following description focuses on differences from the semiconductor package and coil structures shown in FIGS. 20 and 21.

In FIG. 22, according to some implementations, a semiconductor package includes the first conductive structure 600 placed inside the first substrate 100, the through via structure 700 placed inside the second substrate 200, and the third conductive structure 800 placed inside the semiconductor chip 300.

One end of the first conductive structure 600 may be electrically connected to the first connecting structure 400. The other end of the first conductive structure 600 may be connected to ground adjacent to the first side 100_1 of the first substrate 100.

The through via structure 700 may be placed between the first connecting structure 400 and the second connecting structure 500. The through via structure 700 may be electrically connected to the first conductive structure 600.

One end of the third conductive structure 800 may be electrically connected to the wiring layer inside the semiconductor chip 300, and the other end of the third conductive structure 800 may be electrically connected to the second connecting structure 500.

The coil structure 900A in FIG. 2 may be similarly applied to the first conductive structure 600. The coil structure 900B in FIG. 3 may be similarly applied to the third conductive structure 800.

In FIG. 23, according to some implementations, a semiconductor package includes the first conductive structure 600 placed inside the first substrate 100, the through via structure 700 placed inside the second substrate 200, and the third conductive structure 800 placed inside the semiconductor chip 300.

One end of the first conductive structure 600 may be electrically connected to the first connecting structure 400. The other end of the first conductive structure 600 may be connected to ground adjacent to the second side 100_2 of the first substrate 100.

The through via structure 700 may be placed between the first connecting structure 400 and the second connecting structure 500. The through via structure 700 may be electrically connected to the first conductive structure 600.

One end of the third conductive structure 800 may be electrically connected to the wiring layer inside the semiconductor chip 300, and the other end of the third conductive structure 800 may be electrically connected to the second connecting structure 500.

The coil structure 900B in FIG. 3 may be similarly applied to each of the first conductive structure 600 and the third conductive structure 800.

In some implementations, by including a stacked inductor a semiconductor package may reduce a loss due to metal components (metal loss) or an eddy current loss, and may increase the Q value.

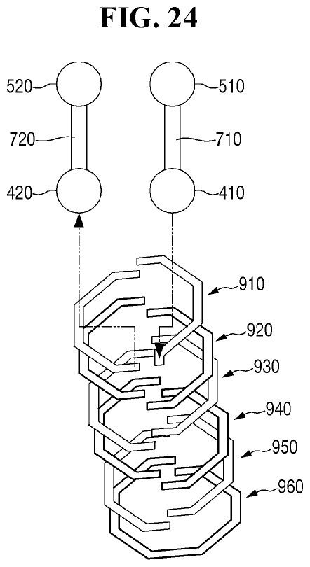

FIG. 24 is a diagram showing an example of a coil structure configured to be included in a semiconductor package according to some implementations. FIG. 24 shows a coil structure and bumps included in a semiconductor package according to some implementations. For efficiency, the following description focuses on differences from the semiconductor packages and coil structure shown in FIGS. 1 to 9, 14 to 17, and 19 to 23.

In FIG. 24, according to some implementations, a first connecting structure (400 of FIG. 19) of a semiconductor package includes first and second bumps 410 and 420 spaced apart from each other in the first direction X. The second connecting structure (500 of FIG. 19) may include first and second bumps 510 and 520 spaced apart from each other in the first direction X.

In FIGS. 14, 15, and 24, the coil structure includes first and second coil structures (900_1, 900_2 of FIG. 15) spaced apart from each other in the first direction X, inside the second substrate 200. One end of the first coil structure (900_1 of FIG. 15) may be electrically connected to the first bump (410 of FIG. 24) of the first connecting structure 400, and may be electrically connected to the first bump (510 of FIG. 2) of the second connecting structure 500. One end of the second coil structure (900_2 of FIG. 15) may be electrically connected to the second bump (420 of FIG. 24) of the first connecting structure 400, and may be electrically connected to the second bump (520 of FIG. 24) of the second connecting structure 500.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor package comprising:
a first substrate that includes a first side and a second side opposite to the first side;
a semiconductor chip on the second side of the first substrate, the semiconductor chip including a third side and a fourth side opposite to the third side;
a second substrate located between the second side of the first substrate and the third side of the semiconductor chip, the second substrate including a fifth side and a sixth side opposite to the fifth side;
a first connecting structure electrically connecting the first substrate and the second substrate, the first connection structure being between the first substrate and the second substrate;
a second connecting structure electrically connecting the second substrate and the semiconductor chip, the second connecting structure being between the second substrate and the semiconductor chip; and
a coil structure that includes a plurality of conductive layers, wherein the coil structure is in at least one of the first substrate, the second substrate, and the semiconductor chip.

2. The semiconductor package of claim 1,
wherein the coil structure includes a first coil structure inside the second substrate, and
wherein the first coil structure includes first to sixth coil parts that are stacked sequentially, and first to fifth vias that electrically interconnect the first to sixth coil parts.

3. The semiconductor package of claim 2,
wherein one end of the first coil structure is electrically connected to the second connecting structure, and
wherein the other end of the first coil structure is electrically connected to ground adjacent to the fifth side of the second substrate.

4. The semiconductor package of claim 2,
wherein one end of the first coil structure is electrically connected to the second connecting structure, and
wherein the other end of the first coil structure is electrically connected to ground adjacent to the sixth side of the second substrate.

5. The semiconductor package of claim 1,
wherein the coil structure includes a first coil structure inside the semiconductor chip, and
wherein the first coil structure includes first to sixth coil parts that are stacked sequentially, and first to fifth vias that electrically interconnect the first to sixth coil parts.

6. The semiconductor package of claim 5, wherein one end of the first coil structure is electrically connected to ground adjacent to the third side of the semiconductor chip.

7. The semiconductor package of claim 5, wherein one end of the first coil structure is connected to ground adjacent to the fourth side of the semiconductor chip.

8. The semiconductor package of claim 1,
wherein the coil structure includes a first coil structure inside the first substrate, and wherein the first coil structure includes first to sixth coil parts that are stacked
sequentially, and first to fifth vias that electrically interconnect the first to sixth coil parts.

9. The semiconductor package of claim 8,
wherein one end of the first coil structure is electrically connected to the first connecting structure, and
wherein the other end of the first coil structure is connected to ground adjacent to the first side of the first substrate.

10. The semiconductor package of claim 8,
wherein one end of the first coil structure is electrically connected to the first connecting structure, and
wherein the other end of the first coil structure is connected to ground adjacent to the second side of the first substrate.

11. The semiconductor package of claim 1, wherein the coil structure includes:
a first coil structure inside the first substrate, and
a second coil structure inside the second substrate.

12. The semiconductor package of claim 1, wherein the coil structure includes:
a first coil structure inside the semiconductor chip, and
a second coil structure inside the second substrate.

13. The semiconductor package of claim 1, wherein the coil structure includes:
a first coil structure inside the first substrate,
a second coil structure inside the second substrate, and
a third coil structure inside the semiconductor chip.

14. The semiconductor package of claim 1,
wherein the coil structure includes first to sixth coil parts that are stacked sequentially, and first to fifth vias that electrically interconnect the first to sixth coil parts,
wherein each of the first to sixth coil parts includes a first coil pattern, and a second coil pattern inside the first coil pattern, and
wherein a width of the first coil pattern is greater than a width of the second coil pattern.

15. A semiconductor package comprising:
a first substrate that includes a first side and a second side opposite to the first side;
a semiconductor chip on the second side of the first substrate, the semiconductor chips including a third side and a fourth side opposite to the third side;
a second substrate between the second side of the first substrate and the third side of the semiconductor chip, the second substrate including a fifth side and a sixth side opposite to the fifth side;
a first connecting structure electrically connecting the first substrate and the second substrate, the first connecting structure being between the first substrate and the second substrate;
a second connecting structure electrically connecting the second substrate and the semiconductor chip, the second connecting structure being between the second substrate and the semiconductor chip;
a coil structure that includes a plurality of conductive layers, the coil structure being in at least one of the first substrate and the semiconductor chip; and
a through via structure between the first connecting structure and the second connecting structure inside the second substrate, the through via structure being electrically connected to the coil structure.

16. The semiconductor package of claim 15,
wherein the coil structure includes a first coil structure inside the first substrate,
wherein one end of the first coil structure is electrically connected to the second connecting structure, and
wherein the other end of the first coil structure is connected to ground adjacent to the first side of the first substrate.

17. The semiconductor package of claim 15,
wherein the coil structure includes a first coil structure inside the first substrate,
wherein one end of the first coil structure is electrically connected to the second connecting structure, and
wherein the other end of the first coil structure is connected to ground adjacent to the second side of the first substrate.

18. The semiconductor package of claim 15, wherein the coil structure includes:
a first coil structure inside the semiconductor chip, and
a second coil structure inside the first substrate,
wherein one end of the first coil structure is electrically connected to the second connecting structure,
wherein one end of the second coil structure is electrically connected to the first connecting structure, and
wherein the other end of the second coil structure is connected to ground adjacent to the first side of the first substrate.

19. The semiconductor package of claim 15, wherein the coil structure includes:
a first coil structure inside the semiconductor chip, and
a second coil structure inside the first substrate,
wherein one end of the first coil structure is electrically connected to the second connecting structure,
wherein one end of the second coil structure is electrically connected to the first connecting structure, and
wherein the other end of the second coil structure is connected to ground adjacent to the second side of the first substrate.

20. A semiconductor package comprising:
a first substrate that includes a first side and a second side opposite to the first side;
a semiconductor chip on the second side of the first substrate, the semiconductor chip including a third side and a fourth side opposite to the third side;
a second substrate between the second side of the first substrate and the third side of the semiconductor chip, the second substrate including a fifth side and a sixth side opposite to the fifth side;
a first connecting structure electrically connecting the first substrate and the semiconductor chip, the first connecting structure being between the first substrate and the semiconductor chip; and
a coil structure that includes a plurality of conductive layers, the coil structure being in at least one of the first substrate, the second substrate, and the semiconductor chip, wherein the first connecting structure includes first and second bumps spaced apart from
each other in a horizontal direction,
wherein the coil structure includes a first coil structure and a second coil structure spaced apart from each other in the horizontal direction,
wherein one end of the first coil structure is electrically connected to the first bump, and
wherein one end of the second coil structure is electrically connected to the second bump.

21. (canceled)
